(19) United States
(12) Patent Application Publication
(10) Pub. No.: US 2026/0100685 A1
(43) Pub. Date: Apr. 9, 2026

(54) CURRENT MIRROR OPERATIONAL TRANSCONDUCTANCE AMPLIFIER

(71) Applicant: SEMICONDUCTOR COMPONENTS INDUSTRIES, LLC, Scottsdale, AZ (US)

(72) Inventors: Bharat BALAR, Bengaluru (IN); Mehak SOOD, Bengaluru (IN)

(73) Assignee: SEMICONDUCTOR COMPONENTS INDUSTRIES, LLC, Scottsdale, AZ (US)

(21) Appl. No.: 18/909,439

(22) Filed: Oct. 8, 2024

(51) Int. Cl. H03F 3/45

(52) U.S. Cl. CPC H03F 3/45273; H03F 3/45237; H03F 3/45264

(57) ABSTRACT

Systems, devices, and methods are described to provide an improved current mirror operational transconductance amplifier (OTA). Improved OTAs may include an input circuit arranged to receive a differential voltage input, a load circuit arranged to measure a positive branch current and negative branch current from the input circuit, a bias circuit arranged to determine a bias voltage based on the negative branch current, a folded current branch circuit arranged to generate an adaptive bias current and a pass transistor configured to adjust an amount of the adaptive bias current based on the bias voltage, and a push-pull output circuit configured to sink current based on the adjusted adaptive bias current. The folded current branch circuit may generate the adaptive bias current based on the measured negative branch current. The output circuit may source current based on the measured positive branch current. Advantageously, most transistors may be of minimum size.

### BACKGROUND

This application relates generally to operational transconductance amplifiers and, more particularly, to current mirror-based operational transconductance amplifiers.

Operational transconductance amplifiers (OTAs) are used in many electronic circuits for various applications, such as voltage-controlled amplifiers, filters, image sensors, other analog circuits, and the like. For example, OTAs may be used with the readout circuitry of a CMOS image sensor. OTAs generally convert an input voltage signal into an output current. An OTA may amplify the voltage difference between two input terminals to produce a proportional output current. The ratio of the output current to the input voltage difference is referred to as the transconductance, or gₘ, of the OTA.

A current mirror OTA uses a current mirror configuration to generate the output current proportional to the input voltage. Current mirror OTAs have a differential pair of input transistors receiving the differential input voltage (e.g., on respective control terminals). The difference in voltage controls the current flowing through each transistor of the differential pair, which is mirrored to control one or more output transistors to create the output current. For example, the output transistors may be arranged as a push-pull pair, and each may be driven according to a respective current mirror corresponding to the respective transistor of the differential pair. OTAs may be implemented using a variety of transistor types, for example MOSFET, BJT, or the like.

The bandwidth of an OTA refers to the frequency range over which the OTA can effectively amplify signals without significant attenuation or distortion, for example in which the DC gain remains relatively constant within certain tolerances. The slew rate of the output current of an OTA refers to the rate at which the output current can change in response to a sudden change in the input voltage, for example while still maintaining linearity and stability. When increased performance is required, for example a faster settling time, increased slew rate, or the like, the OTA may be designed with increased current and increased transconductance. This has required increased device sizes, increased area for implementing the OTA, and increased power consumption.

It would therefore be desirable to provide improved current mirror OTA devices and methods having lower power and area requirements.

### BRIEF DESCRIPTION OF DRAWING FIGURES

FIG. 1 is a schematic diagram showing a first exemplary current mirror operational transconductance amplifier (OTA), according to various embodiments.

FIG. 2 is a schematic diagram showing a second exemplary current mirror OTA, according to various embodiments.

FIG. 3 is a schematic diagram showing a third exemplary current mirror OTA, according to various embodiments.

FIG. 4A illustrates a simulated output voltage compared to a differential input voltage for each of the first, second, and third exemplary OTAs, according to various embodiments.

FIG. 4B is a table illustrating additional simulation results for each of the first, second, and third exemplary OTAs, according to various embodiments.

### BRIEF SUMMARY

Various embodiments relate to systems, devices, and methods for current mirror operational transconductance amplifiers.

In various embodiments, an operational transconductance amplifier (OTA) may include an input circuit comprising a first input transistor coupled in parallel with a second input transistor, wherein the first and second input transistors are controllable according to a differential voltage input signal, a load circuit coupled with the input circuit, the load circuit comprising a first reference transistor coupled in series with the first input transistor and a second reference transistor coupled in series with the second input transistor, wherein the first reference transistor is configured to measure a first current through the first input transistor and the second reference transistor is configured to measure a second current through the second input transistor, an output circuit comprising a sourcing transistor coupled in series with a sinking transistor, wherein the sourcing transistor is coupled with the sinking transistor at an output terminal, a folded current branch circuit coupled with the output circuit and comprising a pass transistor, wherein the pass transistor is configured to control a third current flowing through the folded current branch circuit based on a bias voltage and the folded current branch circuit is configured to control the sinking transistor based on the third current, and a bias circuit coupled with the load circuit and the folded current branch circuit and configured to determine the bias voltage based on the measured first current.

In various embodiments, an OTA may include an input circuit configured to generate a positive branch current based on a positive differential input voltage and a negative branch current based on a negative differential input voltage, a load circuit coupled with the input circuit and configured to measure the positive branch current and the negative branch current, a bias circuit coupled with the load circuit and configured to determine a dynamic bias voltage based on the measured negative branch current, an output circuit coupled with the load circuit, wherein the output circuit comprises a push-pull pair of transistors and is configured to source current to an output terminal based on the measured positive branch current, and a folded current branch circuit coupled with the bias circuit and the output circuit and configured to control the output circuit to sink current from the output terminal based on the dynamic bias voltage.

In various embodiments, an OTA may include an input circuit comprising a first input transistor coupled in parallel with a second input transistor, wherein a gate of the first input transistor is configured to receive a negative differential input voltage and a gate of the second input transistor is configured to receive a positive differential input voltage, a load circuit coupled with the input circuit, the load circuit comprising a negative branch current mirror configured to measure a negative branch current through the first input transistor and a positive branch circuit mirror configured to measure a positive branch current through the second input transistor, wherein the negative branch current mirror and positive branch current mirror are cross coupled, a folded current branch circuit coupled with an output circuit, wherein the folded current branch circuit comprises a pass transistor configured to adjust an amount of an adaptive current based on a bias voltage and the folded current branch circuit is configured to control the output circuit to sink an output current at an output terminal based on the adjusted adaptive current, and a bias circuit coupled with the load circuit and the folded current branch circuit and configured to determine the bias voltage based on the measured negative branch current.

These and other examples are described in increasing detail below.

### DETAILED DESCRIPTION

The following detailed description is intended to provide several examples that will illustrate the broader concepts that are set forth herein, but it is not intended to limit the invention or the application and uses of the invention. Furthermore, there is no intention to be bound by any theory presented in the preceding background or the following detailed description.

According to various embodiments, current mirror OTA circuits and methods are used to measure the difference between a differential voltage input signal and drive an output current accordingly, for example sourcing the output current if the positive voltage input signal respectively increases and sinking the output current if the negative voltage input signal respectively increases. Various embodiments may include improved circuits that increase or otherwise improve the transconductance, gain, bandwidth, slew rate, settling time, and stability of the current mirror OTA, without a large increase in circuit size and while maintaining the ability to use minimum-sized transistors.

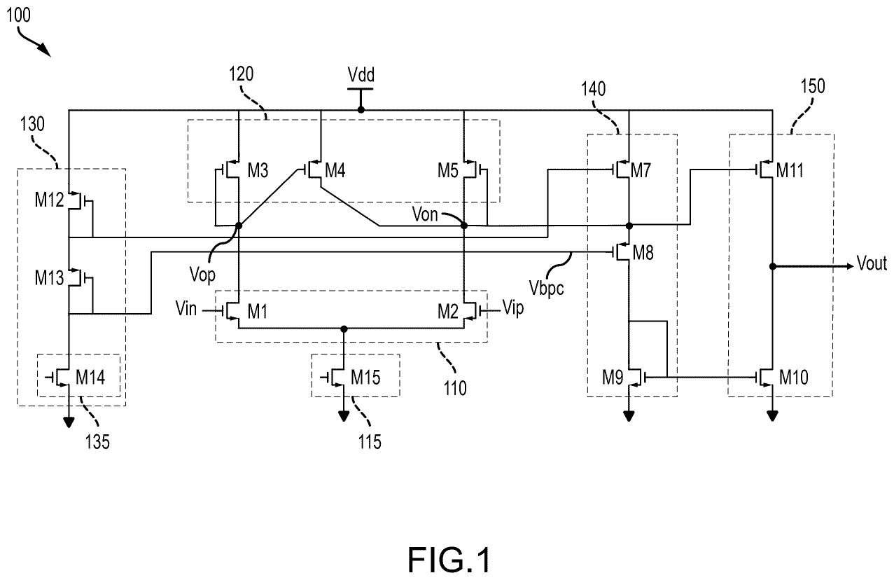

FIG. 1 illustrates an exemplary embodiment of a first current mirror OTA 100 circuit. The OTA 100 may include an input circuit 110 configured to receive a differential voltage input signal. In some embodiments, the input circuit 110 may include differential input pair of transistors, for example a first input transistor M1 configured to receive the respective negative input Vin of the differential voltage input signal and a second input transistor M2 configured to receive the respective positive input Vip of the differential voltage input signals. The negative input node Vin may be referred to as the inverting input of the OTA 100, and the positive input node Vip may be referred to as the non-inverting input of the OTA 100.

The differential pair transistors M1, M2 may be coupled in parallel, with the first input transistor M1 on the negative branch of the input circuit 110 and the second input transistor M2 on the positive branch of the input circuit 110. The differential pair transistors M1, M2 may receive the respective input signals on their control terminals, for example the gate terminal of a field effect transistors (FETs). In some embodiments, the differential pair transistors M1, M2 may be N-channel metal-oxide semiconductor (NMOS) transistors.

The input circuit 110 may be coupled in series with a tail current source 115 configured to provide a constant current. The tail current source 115 may be coupled in series between the input circuit 110 and a common voltage node such as ground. The tail current source 115 may comprise any suitable current source, such as a current mirror, resistor, biased transistor, or the like. During operation of the OTA 100, the respective currents through the differential pair transistors M1, M2 may change as the positive and negative input signals at Vin, Vip change, but will sum to the current determined by the tail current source 115.

In some embodiments, the tail current source 115 may include a tail transistor M15 biased, for example as part of a current mirror (not shown), to provide a constant current to the differential pair transistors M1, M2. The tail transistor M15 may be a MOSFET, such as an NMOS transistor, having its source terminal coupled to the common voltage node and its drain coupled to the source terminals of the first input transistor M1 and the second input transistor M2. In various embodiments, the differential pair transistors M1, M2 may be sized independently from each other or may be matched. In various embodiments, the differential pair transistors M1, M2 need not be matched or sized with respect to the tail transistor M15 and/or the tail current source 135 tail transistor M14 (discussed below).

The input circuit 110 may also be coupled in series with a load circuit 120 configured to help determine one or more internal voltages reference nodes based on the respective currents flowing through the differential pair transistors M1, M2. The load circuit 120 may be coupled between the input circuit 110 and a supply voltage terminal, for example providing a digital operating voltage Vdd or the like. The load circuit 120 may comprise one or more devices coupled in series with the negative branch of the input circuit 110, and one or more devices coupled in series with the positive branch of the input circuit 110.

In some embodiments, the load circuit 120 may include a negative-side current mirror having a reference transistor M3 coupled in series between the supply voltage Vdd and the first input transistor M1 on the negative branch of the input circuit 110. The negative-side current mirror may further include a mirror transistor M4 (also referred to herein as the load mirror transistor M4) configured to mirror the current measured by the reference transistor M3. The negative-side current mirror may be referred to as the M3-M4 current mirror, and the negative-side reference transistor M3 may be referred to as the first load reference transistor M3. In some embodiments, the reference transistor M3 may comprise a diode-connected MOSFET, such as a PMOS transistor, and the mirror transistor M4 may comprise a MOSFET, such as a PMOS transistor, having a control terminal coupled with the control terminal of the reference transistor M3.

For example, the reference transistor M3 may have its source terminal coupled with the supply voltage Vdd, and its drain and gate terminals coupled with the first input transistor M1 at a positive internal voltage reference node Vop (also referred to herein as the positive reference node). The mirror transistor M4 may have its gate terminal coupled to the positive reference node Vop, its source terminal coupled with the supply voltage Vdd, and its drain terminal coupled with a negative internal voltage reference node Von (also referred to herein as the negative reference node). As used herein, a voltage reference node may provide a reference voltage for use by the various circuits and components.

The load circuit 120 may further include a diode-connected transistor M5, such as a PMOS transistor, coupled in series between the supply voltage Vdd and the second input transistor M2 on the positive branch of the input circuit 110. For example, the transistor M5 may be configured as the reference transistor of a current mirror, with a corresponding mirror transistor located in an output circuit 150. The reference transistor M5 may have its source terminal coupled with the supply voltage Vdd, and its drain and gate terminals coupled with the second input transistor M2 at the negative reference node Von. The reference transistor M5 may be referred to as the second load reference transistor M5.

Generally, as the positive input signal Vip increases with respect to the negative input signal Vin, the voltage at the positive reference node Vop will increase and the voltage at the negative reference node Von will decrease. Likewise, as the positive input signal Vip decreases with respect to the negative input signal Vin, the voltage at the positive reference node Vop will decrease and the voltage at the negative reference node Von will increase. Other load circuit 120 configurations may be implemented, for example load resistors, to determine the voltages of the reference nodes Vop, Von with respect to the differential voltage input signal.

The OTA 100 may further include an output circuit 150 configured to source current to or sink current from a load (not shown) in response to the positive and negative input signals Vin, Vip. In some embodiments, the output circuit 150 may comprise one or more transistors configured to source and/or sink current from a load at an output terminal Vout of the OTA 100. For example, the output circuit 150 may include a push-pull arrangement of transistors, for example MOSFETs, configured to source and/or sink current based on the differential voltage input signal. In some embodiments, the output circuit 150 may include a sourcing transistor M11 configured to source current to the load, coupled in series with a sinking transistor M10 configured to sink current from the load.

The load may be connected between the sourcing transistor M11 and the sinking transistor M10. For example, the sourcing transistor M11 may be a PMOS transistor having its source terminal coupled with the supply voltage Vdd and its drain terminal coupled with the output terminal Vout, and the sinking transistor M10 may be an NMOS transistor having its source terminal coupled with the common voltage node and its drain terminal coupled with the output terminal Vout.

In some embodiments, the sourcing transistor M11 may be a mirror transistor with respect to the reference transistor M5 on the positive branch of the load circuit 120, and may have its control terminal coupled with the negative reference node Von. This current mirror may be referred to as the M5-M11 current mirror. For example, as the positive input signal Vip increases with respect to the negative input signal Vin and the voltage at the negative reference node Von decreases, the Vgs of the sourcing transistor M11 will increase and the sourcing current will increase. The sourcing transistor M11 will mirror the increased current through the second load reference transistor M5.

The OTA 100 may further include a bias circuit 130 and a folded current branch circuit 140. The bias circuit 130 may include any suitable configuration of components configured to generate one or more bias voltages for the folded current branch circuit 140. In some embodiments, the bias circuit 130 may include a first reference transistor M12, a second reference transistor M13, and a tail current source 135. The first reference transistor M12, second reference transistor M13, and tail current source 135 may be coupled in series, and in some embodiments may comprise PMOS and/or NMOS transistors. The first reference transistor M12 and second reference transistor M13 may provide fixed bias voltages to the folded current branch circuit 140, and may be referred to herein as the first bias reference transistor M12 and the second bias reference transistor M13, respectively.

For example, the first bias reference transistor M12 may be a diode-connected PMOS transistor having its source terminal coupled with the supply voltage Vdd and its gate and drain terminals coupled with the source terminal of the second reference transistor M13, and the second bias reference transistor may be a diode-connected PMOS transistor having its gate and drain terminals coupled with the tail current source 135. The tail current source 135 may be configured to provide a constant current through the first and second bias reference transistors M12, M13, and may comprise any suitable current source, such as a current mirror, resistor, biased transistor, or the like.

In some embodiments, tail current source 135 may include a tail transistor M14 biased, for example as part of a current mirror (not shown), to provide a constant current. The tail transistor M14 may be a MOSFET, such as an NMOS transistor, having its source terminal coupled to the common voltage node and its drain coupled to the drain of the second bias reference transistor M13. In various embodiments, the tail transistor M15 need not be matched, for example not requiring a sizing relation, with the tail current source 135 tail transistor M14.

The folded current branch circuit 140 may be configured to help control the current flowing through the sourcing transistor M11 and/or sinking transistor M10 of the output circuit 150, based on the differential voltage input signals Vin, Vip. The folded current branch circuit 140 may provide a current source that is passed in varying amounts, depending on the differential voltage input signals Vin, Vip, to be mirrored by the sourcing transistor M11 and/or sinking transistor M10. In some embodiments, the folded current branch circuit 140 may include a mirror transistor M7, a pass transistor M8, and a reference transistor M9. The mirror transistor M7, pass transistor M8, and reference transistor M9 may be coupled in series.

The mirror transistor M7 (also referred to herein as the current branch mirror transistor M7) may be configured to mirror the current measured through the first bias reference transistor M12, for example to provide a current source for the folded current branch circuit 140. The mirror transistor M7 may have its control terminal coupled with the control terminal of the first reference transistor M12 of the bias circuit to create the M12-M7 current mirror. In some embodiments, the mirror transistor M7 may be a PMOS transistor having its source terminal coupled with the supply voltage Vdd and its drain terminal coupled with the negative reference node Von.

The pass transistor M8 may be configured to pass a varying amount of the current provided by the mirror transistor M7, depending on the fixed bias provided by the second bias reference transistor M13 and the voltage of the negative reference node Von. The pass transistor M8 therefore may adjust the amount of the current provided by the mirror transistor M7. The pass transistor M8 may be a PMOS transistor having its source terminal coupled with the negative reference node Von, its drain coupled with the reference transistor M9, and its control terminal coupled with the control terminal of the second bias reference transistor M13 of the bias circuit 130. The second bias reference transistor M13 and the pass transistor M8 may form a current mirror referred to as the M13-M8 current mirror. The pass transistor M8 and the second load reference transistor M5 may act as loads on the negative reference node Von.

The reference transistor M9 (also referred to herein as the current branch reference transistor M9) may be configured as the reference transistor in a current mirror. In some embodiments, the current branch reference transistor M9 may measure the current through the pass transistor M8 for mirroring by the sinking transistor M10 of the output circuit 150, creating the M9-M10 current mirror. For example, the current branch reference transistor M9 may be a diode-connected NMOS transistor having its gate and drain terminals coupled with the drain terminal of the pass transistor M8 and its source terminal coupled with the common voltage node. The gate of the current branch reference transistor M9 may be coupled with the gate of the sinking transistor M10.

Accordingly, a varying amount of the current from the mirror transistor M7 will pass through the pass transistor M8 and reference transistor M9 for mirroring by the sinking transistor M10, acting as a pull down current. Generally, as the positive input signal Vip increases with respect to the negative input signal Vin and the voltage at the negative reference node Von decreases, the voltage difference between the gate and source (Vgs) of the pass transistor M8 will decrease, causing a decrease in the current from the mirror transistor M7 that passes through the pass transistor M8. The decreased current through the pass transistor M8 is measured by the current branch reference transistor M9 and mirrored to sinking transistor M10, causing a decrease in sinking current in the output circuit 150. The decrease in sinking current occurs as the decreasing negative reference node Von causes an increase in sourcing current, thus increasing the current output at the output terminal Vout.

Likewise, as the positive input signal Vip decreases with respect to the negative input signal Vin and the voltage at the negative reference node Von increases, the voltage difference between the gate and source (Vgs) of the pass transistor M8 will increase, causing an increase in the current from the mirror transistor M7 that passes through the pass transistor M8. The increased current through the pass transistor M8 is measured by the current branch reference transistor M9 and mirrored to sinking transistor M10, causing an increase in sinking current in the output circuit 150. The increase in sinking current occurs as the increasing negative reference node Von causes a decrease in the sourcing current. Accordingly, a small change in the differential voltage input signals Vin, Vip can cause a large swing in the output current at the output terminal Vout.

The various transistors of the OTA 100 may be sized or otherwise selected to have one or more gain values, transconductance values, and/or other parameters tuned to provide desired performance of the OTA 100. For example, the transistors of the OTA 100 comprise MOSFET transistors having one or more width to length (W/L) ratios, with the relative strength of the transistor increasing with increasing ratio. The various W/L ratios described herein are merely exemplary and may be varied depending on process parameters, design rules and requirements, and the like.

In some embodiments, the pass transistor M8 and the current branch mirror transistor M7 may be selected (for example, configured) to have the minimum size allowed by the relevant process technology, for example a W/L ratio of 1, and the current branch reference transistor M9 may also be selected to have a minimum size, for example a W/L ratio of 1. In other embodiments, the transistors of the folded current branch circuit 140 may be selected to not have the same W/L ratio.

In some embodiments, the first and second input transistors M1, M2 may be configured with the same W/L ratio, for example 1. The tail transistors M15 and M14 may be configured with the same or different W/L ratios, for example both having a W/L ratio of 1. Similarly, the first and second bias reference transistors M12, M13 may be configured with a W/L ratio of 1. In some embodiments, the first and second bias reference transistors M12, M13 may be selected to not have the same W/L ratio.

The first load reference transistor M3 may be selected to have a W/L ratio equal to the sum of the W/L ratios for the second load reference transistor M5 and the load mirror transistor M4. In some embodiments, the load mirror transistor M4 may be selected to have a W/L ratio equal to the variable M, where M is greater than 1 (e.g., greater than the minimum transistor size). Further, the first load reference transistor M3 may be selected to have a W/L ratio of M+1, and the second load reference transistor M5 may be selected to have a W/L ratio of 1.

In some embodiments, the sourcing transistor M11 and sinking transistor M10 may be selected to have the same W/L ratio. The sourcing and sinking transistors M11, M10 may be selected to have a W/L ratio equal to the variable N, where N is greater than 1. The W/L ratios of M and N may be set independently. For example, in some embodiments, M may be set between about 2 and about 4, and N may be set between about 2 and about 4. Any suitable values may be selected based on design requirements, desired performance characteristics, and/or the like.

The W/L ratios of the various transistors may be selected based on desired performance, process parameters, design requirements, and the like. For example, the ratios of the reference transistor and mirror transistor of a current mirror may be selected to determine the ratio of the current measured by the reference transistor that will be provided by the mirror transistor. With the W/L ratios selected as described according to the example above, the following relationships hold:

$${V}_{op} = \frac{{g}_{mn} {V}_{d}}{( M + 1 ) {g}_{mp}} ; \qquad ( equation 1 )$$

$${V}_{on} = \frac{- {g}_{mn} {V}_{d} [ \frac{M}{M + 1} + 1 ]}{( {g}_{mp} + {g}_{mpc} )} ; and \qquad ( equation 2 )$$

$${G}_{mota} = {g}_{mn} \times \frac{N}{2} ( 1 + \frac{M}{M + 1} ) ; \qquad ( equation 3 )$$

where V_{d} equals the positive input Vip or negative input Vin (such that 2V_{d} equals the differential input signal), gₘₙ is the transconductance of the NMOS transistors unless stated otherwise, gₘₚ is the transconductance of the PMOS transistors unless stated otherwise, g_{mpc} is the transconductance of the pass transistor M8, and Gₘₒₜₐ is the transconductance of the OTA 100.

Vₒₚ is determined by solving Kirchhoff's Current Law (KCL) at node Vop, Vₒₙ is determined by solving KCL at node Von (ignoring the effect of the current branch mirror transistor M7), and Gₘₒₜₐ is determined by solving KCL at the output terminal Vout.

In some embodiments, the transconductance of the various NMOS transistors may be matched, and the transconductance of the various PMOS transistors may be matched. In some embodiments, the transconductance of the pass transistor M8 may be selected such that g_{mpc}=gₘₚ. In some embodiments, the transconductance of the pass transistor M8 may be selected to be different from gₘₚ. In some embodiments, the various NMOS transistors, and the PMOS transistors, may be sized differently while keeping the current density matched.

In the previous discussion, some terminals of the transistors were described in general terms such as “control node” or “control terminal” instead of base or gate. These general terms are used to emphasize that the circuits described herein can be implemented with a variety of transistor types. In a similar manner, the terms “source terminal,” “drain terminal,” and “gate terminal” used herein may be replaced by respective terms based on the transistor type, such as emitter, collector, or base, cathode or anode (e.g., if replacing with a diode), and the like. Similarly, one or more of the current mirrors may be configured to source or sink current. In addition, the circuits described above may be configured using other suitable arrangements of PMOS and NMOS transistors (or equivalents of other transistor types).

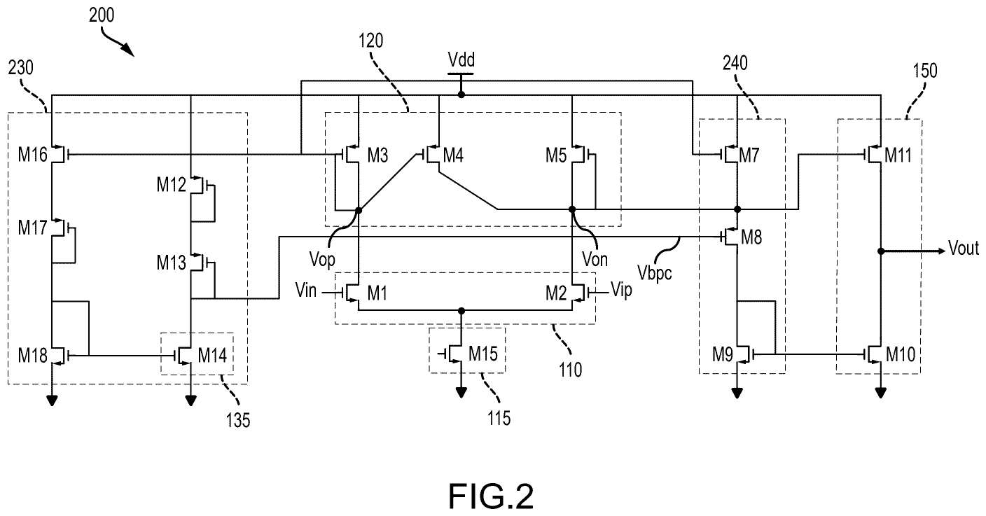

FIG. 2 illustrates an exemplary embodiment of a second current mirror OTA 200 circuit. In some embodiments, the input circuit 110, tail current source 115, load circuit 120, and output circuit 150 may be same as described above. The second current mirror OTA 200 may include a dynamic folded current branch circuit 240 and a dynamic bias circuit 230. In some embodiments, the dynamic folded current branch circuit 240 may include the same series arrangement of transistors M7, M8, M9 as described above but having one or more of the transistors with dynamic biasing.

The dynamic bias circuit 230 may be configured to adaptively determine a gate bias voltage Vbpc for the pass transistor M8 of the dynamic folded current branch circuit 240. The dynamic bias circuit 230 may measure the current through the first input transistor M1 which may then be used to determine the pass transistor M8 gate voltage Vbpc. The electrical node to which the M8 gate is coupled may be referred to as the Vbpc node.

In some embodiments, the dynamic bias circuit 230 may include the same series arrangement of transistors M12, M13, M14 as described above, and a second series arrangement of transistors coupled in parallel to the series arrangement of the reference transistors M12, M13 and tail current source 135. For example, the dynamic bias circuit 230 may include a first mirror transistor M16 (also referred to herein as the first bias mirror transistor M16) configured to measure the current through the first input transistor M1, and a current mirror configured to measure the current through the first mirror transistor M16 to bias the Vbpc node.

In some embodiments, the first bias mirror transistor M16 may comprise MOSFET, such as a PMOS transistor, having its gate terminal coupled with the positive reference node Vop and its source terminal coupled with the supply voltage Vdd. The first bias mirror transistor M16 may form a current mirror with the first load reference transistor M3, which may be referred to herein as the M3-M16 current mirror. The first bias mirror transistor M16 may mirror the current measured by the first load reference transistor M3.

The dynamic bias circuit 230 may include a third reference transistor M18 (also referred to herein as the third bias reference transistor M18) coupled in series between the common voltage node and the first bias mirror transistor M16. The third bias reference transistor M18 may be configured to measure the current mirrored by the first bias mirror transistor M16. In some embodiments, the third bias reference transistor M18 may comprise a diode-connected MOSFET, such as an NMOS transistor. The third bias reference transistor M18 may have its source terminal coupled with the common voltage node, and its drain and gate terminals coupled (directly or indirectly) with the drain terminal of the first bias mirror transistor M16.

In some embodiments, a second bias mirror transistor M17 may be configured as a diode-connected MOSFET, for example a PMOS transistor, coupled in series between the first bias mirror transistor M16 and the third bias reference transistor M18 to facilitate measurement of the current through the first input transistor M1. For example, the second bias mirror transistor may have its gate and drain terminals coupled with the drain terminal of the third bias reference transistor M18, and its source terminal coupled with the drain terminal of the first bias mirror transistor M16.

The gate terminal of the third bias reference transistor M18 may control the tail current source 135 to provide a variable current based on the current measured by the third bias reference transistor M18. In some embodiments, the gate terminal of the third bias reference transistor M18 may be coupled with the gate terminal of the tail transistor M14 to form the M18-M14 current mirror, which may provide a variable current through the first and second bias reference transistors M12, M13. The variable current through the second bias reference transistor M13 will provide a dynamic bias to the pass transistor M8. The first bias reference transistor M12 will provide a voltage at the source terminal of the second bias reference transistor M13 similar to or the same as the voltage at the node Vop. The dynamic bias circuit 230 may therefore determine a dynamic gate voltage Vbpc for the pass transistor M8 based on the change in the positive reference node Vop, and the change in the gate voltage Vbpc is a scaled version of the change in the positive reference node Vop.

For example, if the positive input signal Vip increases with respect to the negative input signal Vin, the voltage at the positive reference node Vop will increase and the voltage at the negative reference node Von will decrease. The current through the first input transistor M1 will decrease, causing current mirrors M3-M16 and M18-M14 to decrease the current measured. The tail transistor M14 will provide a reduced current, increasing the gate voltage Vbpc of the pass transistor M8. The simultaneous reduction in the source terminal voltage of the pass transistor M8 (the negative reference node Von) and increase in the gate voltage Vbpc will cause the pass transistor M8 to quickly reduce the amount of current it passes and may cause it to turn off. This cuts off most or all of the pull-down current sent to the current branch reference transistor M9 and thus to the sinking transistor M10. The sourcing slew current is given by: N×I_{M15}.

Likewise, as the positive input signal Vip decreases with respect to the negative input signal Vin, the voltage at the positive reference node Vop will decrease and the voltage at the negative reference node Von will increase. The gate voltage Vbpc of the pass transistor will decrease and the source terminal voltage of the pass transistor M8 will increase, causing the pass transistor M8 to quickly increase the amount of current it passes. The pass transistor M8 may carry the entire tail current, and the sinking transistor M10 may pass a large current. The sinking slew current is given by: N×I_{M15}.

Accordingly, the time required for increasing or decreasing the current at the output terminal Vout in response to a change in the differential input voltage is reduced and the slew rate is improved. The additional dynamic biasing of the gate terminal of the pass transistor M8 allows for faster response to changes in the differential input voltage with smaller or minimum-sized devices (e.g., transistors M7 and M8). Further, in some embodiments, all transistors of the dynamic bias circuit 230 may have a small or minimum W/L ratio, for example a W/L ratio of 1.

As described above, the dynamic folded current branch circuit 240 may include the same arrangement of transistors as described with reference to FIG. 1, but having one or more transistors with dynamic biasing. As described immediately above, the pass transistor may have dynamic gate voltage Vbpc determined by the dynamic bias circuit 230. In some embodiments, the current branch mirror transistor M7 may also have its gate terminal dynamically biased.

Referring still to FIG. 2, the current branch mirror transistor M7 may have its gate terminal coupled with the positive voltage reference node Vop. If the positive input signal Vip increases with respect to the negative input signal Vin, the voltage at the positive reference node Vop will increase. This reduces the current from the current branch mirror transistor M7, which reduces the current measured and mirrored by the M9-M10 current mirror and increases the sourcing current at the output terminal Vout. Likewise, if the positive input signal Vip decreases with respect to the negative input signal Vin, the voltage at the positive reference node Vop will decrease. This increases the current from the current branch mirror transistor M7, which increases the current measured and mirrored by the M9-M10 current mirror and increases the sinking current at the output terminal Vout. The current branch mirror transistor M7 may therefore provide an adaptive current source controlled by the positive voltage reference node Vop.

Accordingly, the current through the current branch mirror transistor M7 becomes dynamic based on the differential voltage input signals. The current branch mirror transistor M7 adds to the small signal current response in both as the differential voltage input signals change in either direction. The increased sourcing and sinking currents at the output for the same input differential voltage provides an increase in the transconductance of the second current mirror OTA 200.

With the W/L ratios selected as described above, for example the M3-M16 and M3-M7 current mirrors having a respective W/L relationship of (M+1):1, the M3-M4 current mirror having a respective W/L relationship of (M+1):M, the M5-M11 and M9-M10 current mirrors having a respective W/L relationship of 1:N, and the M18-M14 and M13-M8 current mirrors having a respective W/L relationship of 1:1, the following equations hold:

$${V}_{op} = \frac{{g}_{mn} {V}_{d}}{( M + 1 ) {g}_{mp}} ; \qquad ( equation 4 )$$

$${V}_{bpc} = ( 1 + \frac{{g}_{mp}}{{g}_{mpc}} ) {V}_{op} ; \qquad ( equation 5 )$$

$$( {V}_{op} - {V}_{on} ) = \frac{2 {g}_{mn} {V}_{d}}{( {g}_{mp} + {g}_{mpc} )} ; and \qquad ( equation 6 )$$

$${G}_{mota} = {g}_{mn} \times N ; \qquad ( equation 7 )$$

where V_{d} equals the positive input Vip or negative input Vin (such that 2V_{d} equals the differential input signal), gₘₙ is the transconductance of the NMOS transistors unless stated otherwise, gₘₚ is the transconductance of the PMOS transistors unless stated otherwise, g_{mpc} is the transconductance of the transistors of the M13-M8 current mirror, and Gₘₒₜₐ is the transconductance of the second current mirror OTA 200. Vₒₚ is determined by solving KCL at node Vop, (Vₒₚ−Vₒₙ) is determined by solving KCL at node Von (including the dynamic effect of the current branch mirror transistor M7 and pass transistor M8), and Gₘₒₜₐ is determined by solving KCL at the output terminal Vout.

Accordingly, the second current mirror OTA 200 has increased transconductance, improved slew rate, and improved stability.

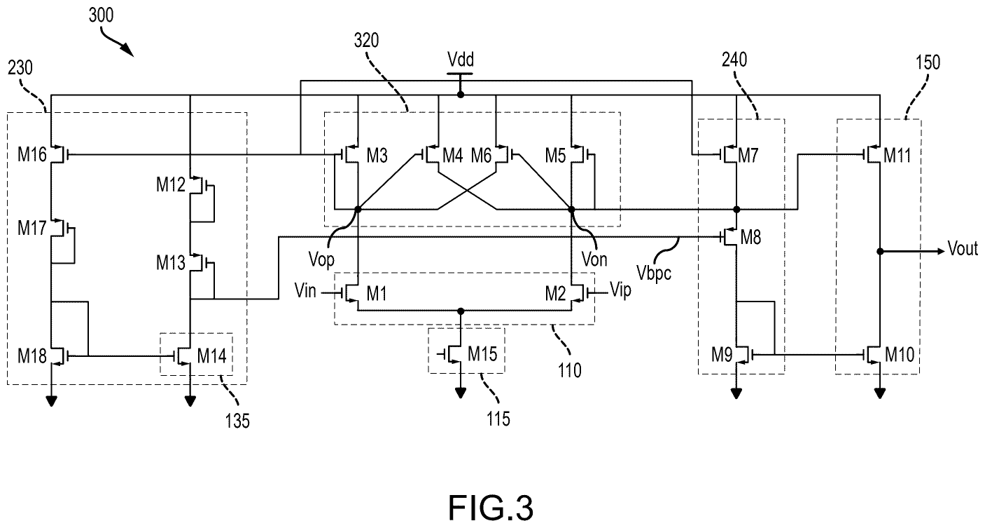

FIG. 3 illustrates an exemplary embodiment of a third current mirror OTA 300 circuit. In some embodiments, the input circuit 110, tail current source 115, dynamic bias circuit 230, dynamic folded current branch circuit 240, and output circuit 150 may be arranged the same as described above with respect to FIG. 2. The third current mirror OTA 300 may include a second load circuit 320 configured to cancel the transconductance of the respective load transistors.

In some embodiments, the second load circuit may include the negative-side M3-M4 current mirror. The second load circuit 320 may further include a positive-side current mirror. For example, the second load circuit 320 may include a second load mirror transistor M6 configured to mirror the current measured by the second load reference transistor M5. This positive-side current mirror may be referred to as the M5-M6 current mirror, and the transistors of the load circuit 320 may be referred to as the load transistors.

The M5-M6 current mirror may be cross coupled with the M3-M4 current mirror. In some embodiments, the second load mirror transistor M6 may comprise a MOSFET, such as a PMOS transistor, having its gate terminal coupled with the gate terminal of the second load reference transistor M5. The second load mirror transistor M6 may have its source terminal coupled with the supply voltage Vdd and its drain terminal coupled with the positive reference node Vop. As described above, the second load reference transistor M5 may comprise a diode-connected transistor, for example a PMOS transistor, coupled between the supply voltage Vdd and the negative reference node Von.

In some embodiments, the W/L ratio for the first load reference transistor M3 and the first load mirror transistor M4 may be selected as M, and the W/L ratio for the second load reference transistor M5 and the second load mirror transistor M6 may be selected as 1. With the M3-M4 current mirror may have a W/L relationship of M:M and the M5-M6 current mirror may have a W/L relationship of 1:1, the current through the positive reference node Vop and negative reference node Von due to the M3-M4 and M5-M6 current mirrors may be determined by:

$${I}_{Vop} = {Mg}_{dsp} {V}_{op} + {Mg}_{mp} {V}_{op} + {g}_{mp} {V}_{on} + {g}_{dsp} {V}_{op} ; \qquad ( equation 8 )$$

$${I}_{Von} = - [ {Mg}_{dsp} {V}_{on} + {Mg}_{mp} {V}_{op} + {g}_{mp} {V}_{on} + {g}_{dsp} {V}_{on} ] ; \qquad ( equation 9 )$$

$$I = {I}_{Vop} + {I}_{Von} = \frac{( M + 1 ) {g}_{dsp}}{2} ( {V}_{op} - {V}_{on} ) ; \qquad ( equation 10 )$$

where g_{dsp} is the drain-source conductance of the PMOS transistors.

Therefore, in embodiments according to the second load circuit 320, the transconductance gₘₚ of the load transistors M3, M4, M5, M6 are cancelled. Because of such high impedance from the load transistors M3, M4, M5, M6, there will be larger voltage changes on the positive reference node Vop and negative reference node Von even with a small change in the differential input signals.

With the W/L ratios selected as described above, for example the M3-M16 and M3-M7 current mirrors having a respective W/L relationship of M:1, the M3-M4 current mirror having a respective W/L relationship of M:M, the M5-M11 and M9-M10 current mirrors having a respective W/L relationship of 1:N, and the M5-M6, M18-M14, and M13-M8 current mirrors having a respective W/L relationship of 1:1, the following equations hold:

$${V}_{op} = \frac{{g}_{mn} {V}_{d} - {g}_{mp} {V}_{on}}{M {g}_{mp}} ; \qquad ( equation 11 )$$

$$( {V}_{op} - {V}_{on} ) = \frac{2 {g}_{mn} {V}_{d}}{{g}_{mp}} ; and \qquad ( equation 12 )$$

$${G}_{mota} = {g}_{mn} \times N \times ( 1 + \frac{{g}_{mp}}{{g}_{mpc}} ) ; \qquad ( equation 13 )$$

where V_{d} equals the positive input Vip or negative input Vin (such that 2V_{d} equals the differential input signal), gₘₙ is the transconductance of the NMOS transistors unless stated otherwise, gₘₚ is the transconductance of the PMOS transistors unless stated otherwise, g_{mpc} is the transconductance of the transistors of the M13-M8 current mirror, and Gₘₒₜₐ is the transconductance of the OTA 200. Vₒₚ is determined by solving KCL at node Vop (including the current from transistor M6), (Vₒₚ−Vₒₙ) is determined by solving KCL at node Von (including the dynamic effect of the current branch mirror transistor M7 and pass transistor M8), and Gₘₒₜₐ is determined by solving KCL at the output terminal Vout.

Accordingly, the third current mirror OTA 300 has increased transconductance compared to the second current mirror OTA 200 and the first current mirror OTA 100. In some embodiments, for example when configured as described above, the transconductance of the third current mirror OTA 300 may be approximately double the transconductance of the first current mirror OTA 100. This result is achieved using only a few additional minimum-sized transistors.

The approximate doubling of transconductance can be seen, for example, by comparing equation 3 to equation 13. The DC gain and bandwidth of the third current mirror OTA 300 may therefore also be approximately double the DC gain and bandwidth of the first current mirror OTA 100. The gain and bandwidth are increased due to the cancellation of the transconductance of the load transistors M3, M4, M5, M6. In some alternative embodiments, the second load circuit 320 may be used in conjunction with first current mirror OTA 100 circuit or other current mirror OTA circuits without the improvements described with respect to FIG. 2.

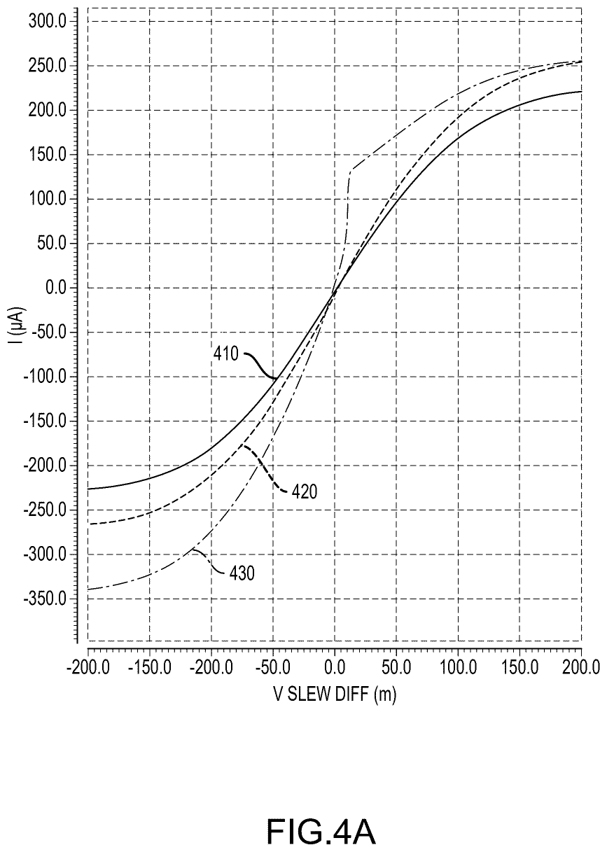

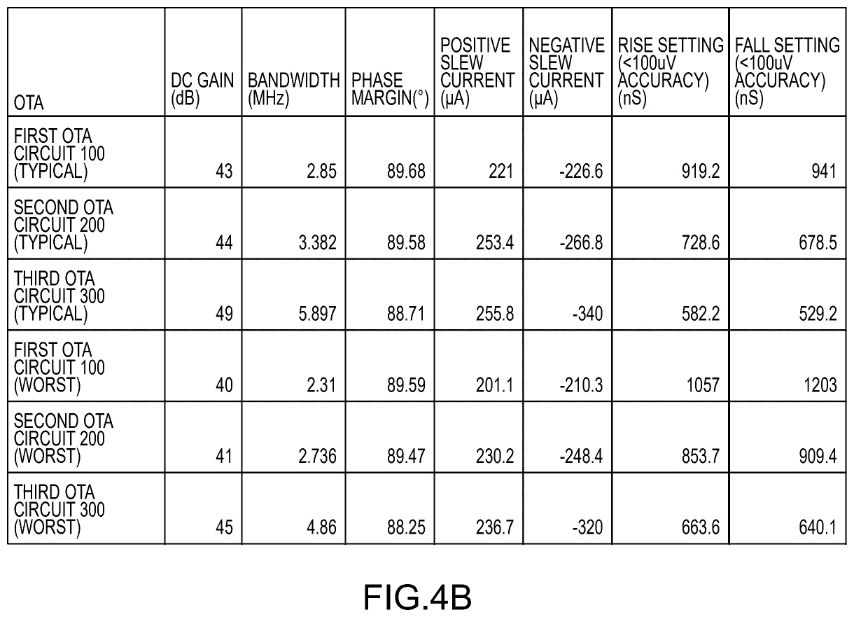

FIGS. 4A and 4B show simulation results for exemplary current mirror OTA circuits according to the first exemplary current mirror OTA 100, the second exemplary current mirror OTA 200, and the third exemplary current mirror OTA 300. Referring to FIG. 4A, each of the exemplary current mirror OTA circuits was simulated with the differential input voltage signal swinging from −200 mV to +200 mV under typical conditions (e.g., typical temperature, etc.). As shown by the first curve 410, the first current mirror OTA 100 had the least amount of negative and positive slew current, at −226.6 μA and +221 μA respectively. As shown by the second curve 420, the second current mirror OTA 200 had improved negative and positive slew current for the same input voltage swing, at −266.8 μA and +253.4 μA respectively. As shown by the third curve 430, the third current mirror OTA 300 had yet further improved negative and positive slew current for the same input voltage swing, at −340 μA and +255.8 μA, respectively.

Referring to FIG. 4B, each of the exemplary current mirror OTA circuits were also simulated to determine other characteristics such as gain, bandwidth, phase margin, negative and positive slew current, and rise and fall settling time, at both typical conditions and under worst-case conditions. The second exemplary current mirror OTA 200 shows similar improvements over the first exemplary current mirror OTA 100 at both typical conditions and worst-case conditions. The third exemplary current mirror OTA 300 shows similar improvements over the first exemplary current mirror OTA 100 at both typical conditions and worst-case conditions. The third exemplary current mirror OTA 300 also shows improvements over the second exemplary current mirror OTA 200.

For example, at worst-case conditions and compared to the first exemplary current mirror OTA 100, the third exemplary current mirror OTA 300 show a 100% improvement in bandwidth, 18% improvement in positive slew current, 52% improvement in negative slew current, 37% improvement in rise settling time, 47% improvement in fall settling time, and a 5 decibel improvement in DC gain. The first, second, and third exemplary current mirror OTAs 100, 200, 300 maintain approximately the same phase margin.

Various embodiments therefore provide improved current mirror OTA circuits and methods. The improved current mirror OTA circuits provide high bandwidth, low power, low area Class AB current mirror OTAs. In contrast to prior current mirror OTA circuits, the improved current mirror OTA circuits have increased slew rate, gain, transconductance, stability, settling time, and other characteristics, with a minimal area increase in a semiconductor substrate. Device sizes and area may be reduced compared to other approaches of increasing transconductance of current mirror OTAs. Improved current mirror OTA circuits as described herein are easily tunable for various applications and design requirements. Other embodiments may provide additional benefits and features, as desired.

The various functions shown and described in the various circuits of the several exemplary embodiments of current mirror OTAs described herein may be distributed in various suitable configurations amongst the various components of the current mirror OTAs and/or circuits and components to which the current mirror OTAs are connected, and different embodiments may organize the various functions and circuits in any number of suitable configurations.

References to a “node” refer to an electrical node unless otherwise specified. Electrical nodes may exist physically at one or more locations, for example as part of a conductive trace that extends from or between one or more electrical devices. Terms such as coupled, connected, or the like refer to electrical coupling unless stated otherwise, and also refer to direct and/or indirect coupling, connection, or the like unless stated otherwise.

The general concepts set forth herein may be adapted to any number of alternate but equivalent embodiments. The term “exemplary” is used herein to represent one example, instance or illustration that may have any number of alternates. Any implementation described herein as “exemplary” is not necessarily to be construed as preferred or advantageous over other implementations, nor is it necessarily intended as a model that must be duplicated in other implementations. While several exemplary embodiments have been presented in the foregoing detailed description, it should be appreciated that a vast number of alternate but equivalent variations exist, and the examples presented herein are not intended to limit the scope, applicability, or configuration of the invention in any way. To the contrary, various changes may be made in the function and arrangement of elements described without departing from the scope of the claims and their legal equivalents.

What is claimed is:

1. An operational transconductance amplifier, comprising:
an input circuit comprising a first input transistor coupled in parallel with a second input transistor, wherein the first and second input transistors are controllable according to a differential voltage input signal;
a load circuit coupled with the input circuit, the load circuit comprising a first reference transistor coupled in series with the first input transistor and a second reference transistor coupled in series with the second input transistor, wherein the first reference transistor is configured to measure a first current through the first input transistor and the second reference transistor is configured to measure a second current through the second input transistor;
an output circuit comprising a sourcing transistor coupled in series with a sinking transistor, wherein the sourcing transistor is coupled with the sinking transistor at an output terminal;
a folded current branch circuit coupled with the output circuit and comprising a pass transistor, wherein the pass transistor is configured to control a third current flowing through the folded current branch circuit based on a bias voltage and the folded current branch circuit is configured to control the sinking transistor based on the third current; and
a bias circuit coupled with the load circuit and the folded current branch circuit and configured to determine the bias voltage based on the measured first current.

2. The operational transconductance amplifier of claim 1, wherein the load circuit is coupled with the output circuit, and wherein the sourcing transistor is controllable according to the measured second current.

3. The operational transconductance amplifier of claim 1, wherein:
the folded current branch circuit is coupled with the load circuit;
the measured first current determines a first reference voltage at a positive reference node;
the folded current branch circuit further comprises a first mirror transistor coupled in series with the pass transistor and controllable according to first reference voltage; and
the bias voltage is a scaled version of the positive reference node.

4. The operational transconductance amplifier of claim 3, wherein the bias circuit further comprises:
a second mirror transistor coupled with the first reference transistor, wherein the first reference transistor and the second mirror transistor are configured as a first current mirror;
a second current mirror coupled with the second mirror transistor and configured to mirror a fourth current provided by the second mirror transistor; and
a third reference transistor coupled in series with the second current mirror and configured to determine the bias voltage based on the mirrored fourth current.

5. The operational transconductance amplifier of claim 4, wherein:
each of the sourcing transistor, sinking transistor, and first reference transistor have a width-to-length (W/L) ratio greater than one; and
each of the pass transistor, first mirror transistor, and second mirror transistor have a W/L ratio approximately equal to one; and
the second current mirror comprises a plurality of transistors, wherein each of the plurality of transistors of the second current mirror has a W/L ratio approximately equal to one.

6. The operational transconductance amplifier of claim 4, wherein:
the pass transistor, first mirror transistor, and second mirror transistor are minimum size transistors;
the second current mirror comprises a plurality of transistors, wherein each of the plurality of transistors of the second current mirror are minimum size transistors; and
the first reference transistor, sourcing transistor, and sinking transistor are larger than minimum size transistors.

7. The operational transconductance amplifier of claim 3, wherein the load circuit further comprises a third current mirror and a fourth current mirror, wherein:
the third current mirror comprises the first reference transistor and a third mirror transistor;
the fourth current mirror comprises the second reference transistor and a fourth mirror transistor; and
the third current mirror is cross coupled with the fourth current mirror between a supply voltage terminal, the positive reference node, and a negative reference node.

8. The operational transconductance amplifier of claim 7, wherein:
the first reference transistor and the third mirror transistor have a width-to-length (W/L) ratio greater than one; and
the second reference transistor and the fourth mirror transistor have a W/L ratio approximately equal to 1.

9. The operational transconductance amplifier of claim 7, wherein the measured second current determines a second reference voltage at the negative reference node.

10. The operational transconductance amplifier of claim 9, wherein:
the first reference transistor is coupled in series between the supply voltage terminal and the positive reference node;
the second reference transistor is coupled in series between the supply voltage terminal and the negative reference node;
the third mirror transistor is coupled in series between the supply voltage terminal and the negative reference node, wherein a control terminal of the third mirror transistor is coupled with the positive reference node; and
the fourth mirror transistor is coupled in series between the supply voltage terminal and the positive reference node, wherein a control terminal of the fourth mirror transistor is coupled with the negative reference node.

11. The operational transconductance amplifier of claim 10, wherein:
the pass transistor is coupled in series between the negative reference node and a common voltage node;
the first mirror transistor is coupled in series between the supply voltage terminal and the negative reference node; and
the sourcing transistor is coupled in series between the supply voltage terminal and the output terminal, wherein a control terminal of the sourcing transistor is coupled with the negative reference node.

12. An operational transconductance amplifier, comprising:
an input circuit configured to generate a positive branch current based on a positive differential input voltage and a negative branch current based on a negative differential input voltage;
a load circuit coupled with the input circuit and configured to measure the positive branch current and the negative branch current;
a bias circuit coupled with the load circuit and configured to determine a dynamic bias voltage based on the measured negative branch current;
an output circuit coupled with the load circuit, wherein the output circuit comprises a push-pull pair of transistors and is configured to source current to an output terminal based on the measured positive branch current; and
a folded current branch circuit coupled with the bias circuit and the output circuit and configured to control the output circuit to sink current from the output terminal based on the dynamic bias voltage.

13. The operational transconductance amplifier of claim 12, wherein the folded current branch circuit comprises:
a first mirror transistor configured to provide an adaptive current to the folded current branch circuit, wherein the first mirror transistor is controlled according to the measured negative branch current; and
a pass transistor coupled in series with the first mirror transistor and configured to adjust an amount of the adaptive current based on the dynamic bias voltage, wherein the sinking of current by the output circuit is controlled according to the adjusted adaptive current.

14. The operational transconductance amplifier of claim 13, wherein the load circuit comprises a positive branch current mirror and a negative branch current mirror, wherein the positive branch current mirror and the negative branch current mirror are cross coupled.

15. The operational transconductance amplifier of claim 14, wherein the load circuit comprises a positive reference node and a negative reference node, wherein:
the load circuit is configured to determine a first reference voltage at the positive reference node based on the measured negative branch current;
the load circuit is configured to determine a second reference voltage at the negative reference node based on the measured positive branch current;
the positive branch current mirror comprises:
a first reference transistor coupled in series between a supply voltage terminal and the positive reference node; and
a second mirror transistor coupled in series between the supply voltage terminal and the negative reference node, wherein a control terminal of the second mirror transistor is coupled with the positive reference node; and
the negative branch current mirror comprises:
a second reference transistor coupled in series between a supply voltage terminal and the negative reference node; and
a third mirror transistor coupled in series between the supply voltage terminal and the positive reference node, wherein a control terminal of the third mirror transistor is coupled with the positive reference node.

16. The operational transconductance amplifier of claim 15, wherein:
the first mirror transistor, pass transistor, first reference transistor, and second mirror transistor are minimum size transistors; and
the push-pull pair of transistors, the second reference transistor, and the third mirror transistor are larger than minimum size transistors.

17. An operational transconductance amplifier, comprising:
an input circuit comprising a first input transistor coupled in parallel with a second input transistor, wherein a gate of the first input transistor is configured to receive a negative differential input voltage and a gate of the second input transistor is configured to receive a positive differential input voltage;
a load circuit coupled with the input circuit, the load circuit comprising a negative branch current mirror configured to measure a negative branch current through the first input transistor and a positive branch circuit mirror configured to measure a positive branch current through the second input transistor, wherein the negative branch current mirror and positive branch current mirror are cross coupled;
a folded current branch circuit coupled with an output circuit, wherein:
the folded current branch circuit comprises a pass transistor configured to adjust an amount of an adaptive current based on a bias voltage; and
the folded current branch circuit is configured to control the output circuit to sink an output current at an output terminal based on the adjusted adaptive current; and
a bias circuit coupled with the load circuit and the folded current branch circuit and configured to determine the bias voltage based on the measured negative branch current.

18. The operational transconductance amplifier of claim 17, wherein the folded current branch circuit further comprises a first mirror transistor configured to provide the adaptive current to the folded current branch circuit and wherein the first mirror transistor is controlled according to the measured negative branch current.

19. The operational transconductance amplifier of claim 18, wherein output circuit comprises a push-pull pair of transistors configured to source current to the output terminal based on the measured positive branch current.

20. The operational transconductance amplifier of claim 19, wherein:
the first mirror transistor and the pass transistor are minimum size transistors;
the push-pull pair of transistors are larger than minimum size transistors;
the negative branch current mirror comprises larger than minimum size transistors; and
the positive branch current mirror comprises minimum size transistors.
